(19) United States
(12) Patent Application Publication
(10) Pub. No.: US 2024/0188226 A1
(43) Pub. Date: Jun. 6, 2024

(54) MANUFACTURING METHOD OF ELECTRONIC DEVICE AND ELECTRONIC DEVICE

(71) Applicant: Innolux Corporation, Miaoli County (TW)

(72) Inventors: Wei-Lun Shieh, Miaoli County (TW); Ying-Jen Chen, Miaoli County (TW); Hang-Lang Lee, Miaoli County (TW)

(73) Assignee: Innolux Corporation, Miaoli County (TW)

(21) Appl. No.: 18/503,138

(22) Filed: Nov. 6, 2023

Related U.S. Application Data
(60) Provisional application No. 63/429,555, filed on Dec. 2, 2022.

(30) Foreign Application Priority Data
Jul. 4, 2023 (CN) 202310812483.4

(51) Int. Cl. H05K 3/40; H05K 1/11; H05K 3/10

(52) U.S. Cl. CPC H05K 3/4046; H05K 1/115; H05K 3/105; H05K 2201/10234; H05K 2203/1105; H05K 2203/1121

(57) ABSTRACT

A manufacturing method of an electronic device including the following steps is provided. First, a first conductive layer is formed on a substrate. Next, a first insulating layer and a second conductive layer are formed on the first conductive layer. The first insulating layer is disposed between the second conductive layer and the first conductive layer, and the first insulating layer has a via exposing a part of the first conductive layer. An aspect ratio of the via of the first insulating layer is greater than 1, and at least part of a sidewall of the first insulating layer is covered by the second conductive layer.

### CROSS-REFERENCE TO RELATED APPLICATION

This application claims the priority benefit of U.S. provisional application Ser. No. 63/429,555, filed on Dec. 2, 2022, and China application serial no. 202310812483.4, filed on Jul. 4, 2023. The entirety of each of the above-mentioned patent applications is hereby incorporated by reference herein and made a part of this specification.

### BACKGROUND

### Technical Field

The disclosure relates to a manufacturing method of an electronic device and the electronic device.

### Description of Related Art

The electronic device generally includes at least one electrical connection structure. In the conventional manufacturing method of the electrical connection structure, a via is formed in an insulating layer, so that two conductive layers disposed on opposite surfaces of the insulating layer may be electrically connected to each other through the via. However, as the aspect ratio of the via increases, the possibility that the two conductive layers are not electrically connected increases due to the via diameter being too small and/or the via depth being too deep, which causes the yield of the electronic device to be reduced.

### SUMMARY

The disclosure provides a manufacturing method of an electronic device, which can reduce the possibility of issues such as reduction in the yield of the manufactured electronic device.

According to some embodiments of the disclosure, a manufacturing method of an electronic device includes the following steps. First, a first conductive layer is formed on a substrate. Next, a first insulating layer and a second conductive layer are formed on the first conductive layer. The first insulating layer is disposed between the second conductive layer and the first conductive layer, and the first insulating layer has a via exposing a part of the first conductive layer. An aspect ratio of the via of the first insulating layer is greater than 1, and at least part of a sidewall of the first insulating layer is covered by the second conductive layer. The disclosure provides an electronic device, which can reduce issues such as reduction in yield.

According to some embodiments of the disclosure, an electronic device includes a substrate, a first conductive layer, a first insulating layer, a second conductive layer, and an electrical connection layer. The first conductive layer is disposed on the substrate. The first insulating layer is disposed on the first conductive layer. The first insulating layer has a via exposing a part of the first conductive layer. The second conductive layer is disposed on the first insulating layer. The second conductive layer is electrically connected to the first conductive layer through the via of the first insulating layer. An aspect ratio of the via of the first insulating layer is greater than 1, and at least part of a sidewall of the first insulating layer is covered by the second conductive layer.

### BRIEF DESCRIPTION OF THE DRAWINGS

FIG. 1 is a schematic cross-sectional flowchart of a manufacturing method of an electronic device according to a first embodiment of the disclosure.

FIG. 2 is a schematic cross-sectional flowchart of a manufacturing method of an electronic device according to a second embodiment of the disclosure.

FIG. 3 is a schematic cross-sectional flowchart of a manufacturing method of an electronic device according to a third embodiment of the disclosure.

FIG. 4 is a schematic cross-sectional flowchart of a manufacturing method of an electronic device according to a fourth embodiment of the disclosure.

FIG. 5 is a schematic cross-sectional flowchart of a manufacturing method of an electronic device according to a fifth embodiment of the disclosure.

FIG. 6 is a schematic cross-sectional flowchart of a manufacturing method of an electronic device according to a sixth embodiment of the disclosure.

FIG. 7 is a schematic cross-sectional flowchart of a manufacturing method of an electronic device according to a seventh embodiment of the disclosure.

FIG. 8 is a schematic cross-sectional flowchart of a manufacturing method of an electronic device according to an eighth embodiment of the disclosure.

FIG. 9A is a schematic top view of an electronic device according to an embodiment of the disclosure.

FIG. 9B is a schematic cross-sectional view of an embodiment according to a section line A-A′ of FIG. 9A.

### DESCRIPTION OF THE EMBODIMENTS

Reference will now be made in detail to the exemplary embodiments of the disclosure, and examples of the exemplary embodiments are illustrated in the drawings. Wherever possible, the same reference numerals are used in the drawings and the description to denote the same or similar parts.

Throughout the specification and the appended claims of the disclosure, certain terms may be used to refer to specific elements. It should be understood by persons skilled in the art that electronic device manufacturers may refer to the same element by different names. The disclosure does not intend to distinguish between elements with the same function but different names. In the following specification and claims, terms such as “including”, “containing”, and “having” are open-ended terms, so the terms should be interpreted as “containing but not limited to . . . ”. Therefore, when the terms “including”, “containing”, and/or “having” are used in the description of the disclosure, the terms designate the presence of a corresponding feature, region, step, operation, and/or component, but do not exclude the presence of one or more corresponding features, regions, steps, operations, and/or components.

Directional terms such as “upper”, “lower”, “front”, “rear”, “left”, and “right” mentioned in the disclosure are only directions with reference to the drawings. Therefore, the used directional terms are used to illustrate, but not to limit, the disclosure. In the drawings, each drawing illustrates the general characteristics of a method, a structure, and/or a material used in a specific embodiment. However, the drawings should not be construed to define or limit the scope or nature covered by the embodiments. For example, for clarity, relative sizes, thicknesses, and positions of film layers, regions, and/or structures may be reduced or enlarged.

When a corresponding component (for example, a film layer or a region) is referred to as being “on another component”, the component may be directly on the other component or there may be another component between the two. On the other hand, when a component is referred to as being “directly on another component”, there is no component between the two. In addition, when a component is referred to as being “on another component”, the two have an upper-lower relationship in the top view direction, and the component may be above or below the other component, and the upper-lower relationship depends on the orientation of the device.

The terms “about”, “equal to”, “equivalent” or “same”, “substantially”, or “roughly” are generally interpreted as within 20% of a given value or range or interpreted as within 10%, 5%, 3%, 2%, 1%, or 0.5% of the given value or range.

Ordinal numbers such as “first” and “second” used in the specification and the claims are used to modify elements, and the terms do not imply and represent that the element(s) have any previous ordinal numbers, nor do they represent the order of a certain element and another element or the order of a manufacturing method. The use of the ordinal numbers is only to clearly distinguish between an element with a certain name and another element with the same name. The claims and the specification may not use the same terms, whereby a first component in the specification may be a second component in the claims.

It should be noted that in the following embodiments, features in several different embodiments may be replaced, recombined, and mixed to complete other embodiments without departing from the spirit of the disclosure. As long as the features of the embodiments do not violate the spirit of the invention or conflict with each other, the features may be arbitrarily mixed and matched for use.

Electrical connection or coupling described in the disclosure may refer to direct connection or indirect connection. In the case of direct connection, terminals of elements on two circuits are directly connected or connected to each other by a conductor segment. In the case of indirect connection, there is a switch, a diode, a capacitor, an inductor, other suitable elements, or a combination of the above elements between the terminals of the elements on the two circuits, but not limited thereto.

In the disclosure, the measurement manner of thickness, length, and width may be by adopting an optical microscope, and the thickness may be obtained by measuring a cross-sectional image in an electron microscope, but not limited thereto. In addition, there may be a certain error in any two values or directions for comparison. If a first value is equal to a second value, it implies that there may be an error of about 10% between the first value and the second value. If a first direction is perpendicular to a second direction, an angle between the first direction and the second direction may be between 80 degrees and 100 degrees; and if the first direction is parallel to the second direction, the angle between the first direction and the second direction may be between 0 degrees and 10 degrees.

An electronic device of the disclosure may include an antenna (for example, a liquid crystal antenna), display, light emission, sensing, touch, splicing, other suitable functions, or a combination of the above functions, but not limited thereto. The electronic device includes a rollable or flexible electronic device, but not limited thereto. A display device may, for example, include liquid crystal, a light emitting diode (LED), quantum dot (QD), fluorescence, phosphor, other suitable materials, or a combination of the above. The light emitting diode may, for example, include an organic light emitting diode (OLED), a micro LED, a mini LED, or a QLED or QDLED, but not limited thereto. An antenna device may, for example, include a frequency selective surface (FSS), a radio frequency (RF) filter, a polarizer, a resonator, an antenna, etc. An electronic element may include a capacitor, a resistor, an inductor, a transistor, a circuit board, a chip, a die, an integrated circuit (IC), a combination of the above elements, or other suitable electronic elements, but not limited thereto.

Exemplary embodiments of the disclosure are illustrated below, and the same reference numerals are used in the drawings and the description to denote the same or similar parts.

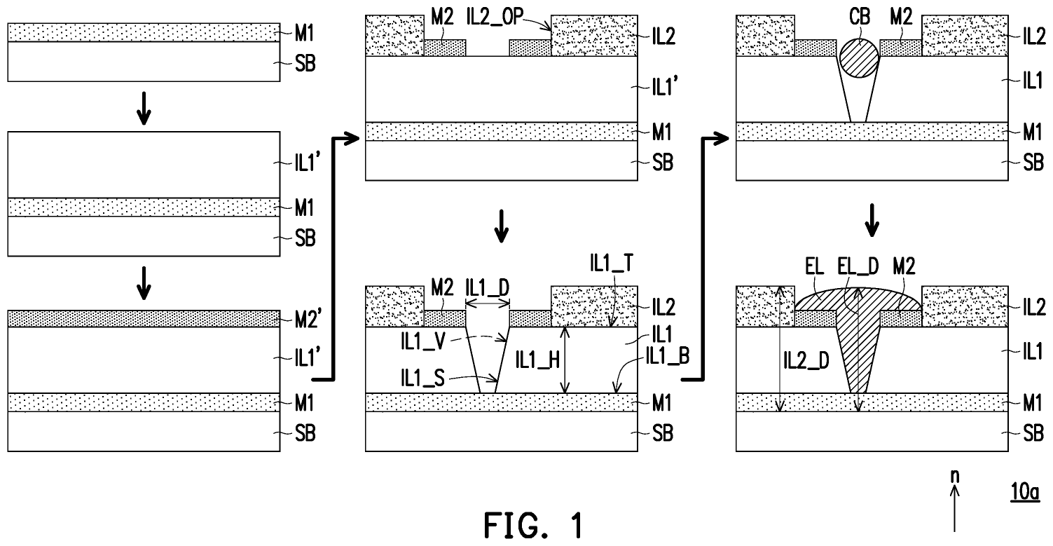

FIG. 1 is a schematic cross-sectional flowchart of a manufacturing method of an electronic device according to a first embodiment of the disclosure.

Please refer to FIG. 1. A first conductive layer M1 is formed on a substrate SB.

The substrate SB has, for example, good support and/or stability, so that the substrate SB may be used to, for example, carry a film layer subsequently formed thereon, and may, for example, withstand the temperature of a subsequent heating process. In some embodiments, the material of the substrate SB may include glass, plastic, other suitable materials, or a combination thereof. In some other embodiments, the substrate SB may be a circuit board, and the disclosure is not limited thereto. In the case where an electronic device 10a is an antenna device, the material of the substrate SB may be selected to have a lower dielectric constant (Dk) and/or have a low dissipation factor (Df), so as to reduce the loss when signals are transmitted therein, but the disclosure is not limited thereto.

A first conductive layer M1 may be formed on the substrate SB through, for example, performing a sputtering process, an electroless plating process, a mounting process, or other suitable processes, but the disclosure is not limited thereto. In some embodiments, the material of the first conductive layer M1 may include metal. For example, the material of the first conductive layer M1 may include copper, aluminum, or other suitable metals, but the disclosure is not limited thereto. In other embodiments, the material of the first conductive layer M1 may include electroless nickel immersion gold (ENIG), which can reduce the possibility of metal oxidation and is beneficial to the electrical connection between a subsequently formed electrical connection layer EL and the first conductive layer M1.

Please continue to refer to FIG. 1. An insulating layer IL1 and a second conductive layer M2 are formed on the first conductive layer M1, wherein the insulating layer IL1 is disposed between the second conductive layer M2 and the first conductive layer M1, and the insulating layer IL1 has a via IL1_V exposing a part of the first conductive layer M1.

In this embodiment, the following steps may be included to form the insulating layer IL1 and the second conductive layer M2 on the first conductive layer M1, but the disclosure is not limited thereto.

(1) First, an insulating material layer IL1′ is formed on the first conductive layer M1. The insulating material layer IL1′ may be formed on the first conductive layer M1 through, for example, performing chemical vapor deposition or other suitable processes, but the disclosure is not limited thereto. In some embodiments, the material of the insulating material layer IL1′ may, for example, be an inorganic material (for example, silicon oxide, silicon nitride, silicon oxynitride, or a stacked layer of at least two of the above materials), an organic material (for example, polyamide amine resin, epoxy resin, or acrylic resin), or a combination thereof, but the disclosure is not limited thereto.

(2) A second conductive material layer M2′ is formed on the insulating material layer IL1′. The second conductive material layer M2′ may be formed on the insulating material layer IL1′ through, for example, performing a sputtering process, an electroless plating process, a mounting process, or other suitable processes, but the disclosure is not limited thereto. In some embodiments, the material of the second conductive material layer M2′ may include metal. For example, the material of the second conductive material layer M2′ may include copper, aluminum, or other suitable metals, but the disclosure is not limited thereto. In some other embodiments, the material of the second conductive material layer M2′ may include electroless nickel immersion gold (ENIG), which can reduce the possibility of metal oxidation and is beneficial to the electrical connection between a subsequently formed electrical connection layer EL and the second conductive layer M2.

(3) A part of the second conductive material layer M2′ is removed to form the second conductive layer M2. The part of the second conductive material layer M2′ may be removed through, for example, performing a patterning process, but the disclosure is not limited thereto. The material of the second conductive layer M2 and the material of the first conductive layer M1 may, for example, be the same as or different from each other, and the disclosure is not limited thereto.

(4) An insulating layer IL2 is formed on the insulating material layer IL1′. The forming method of the insulating layer IL2 may be, for example, first forming an insulating material layer (not shown) on the insulating material layer IL1′ through performing chemical vapor deposition or other suitable processes, and then performing a patterning process on the insulating material layer, but the disclosure is not limited thereto. In this embodiment, the insulating layer IL2 has an opening IL2_OP exposing a part of the insulating material layer IL1′, which may expose a part of the insulating material layer IL1′ together with the second conductive layer M2.

(5) A part of the insulating material layer IL1′ is removed to form the insulating layer IL1 having the via IL1_V, wherein the via IL1_V of the insulating layer IL1 exposes a part of the first conductive layer M1. The via IL1_V of the insulating layer IL1 may be formed through, for example, performing an etching process (for example, a wet etching process), a drilling process (for example, a mechanical drilling process or a laser drilling process), or other suitable processes, and the disclosure is not limited thereto. Viewed from another perspective, the insulating layer IL1 has a top surface IL1_T, a bottom surface IL1_B, and a sidewall IL1_S, wherein the top surface IL1_T of the insulating layer IL1 faces the second conductive layer M2, the bottom surface IL1_B of the insulating layer IL1 faces the first conductive layer M1, and the sidewall IL1_S of the insulating layer IL1 defines the outline of the via IL1_V.

In this embodiment, the aspect ratio of the insulating layer IL1 is greater than 1. The aspect ratio of the insulating layer IL1 is, for example, the ratio between a height IL1_H of the insulating layer IL1 and a via diameter IL1_D of the insulating layer IL1, wherein the via diameter IL1_D of the insulating layer IL1 may, for example, be the diameter or the width of the via IL1_V of the insulating layer IL1. In some embodiments, the aspect ratio of the insulating layer IL1 may be less than 6, but the disclosure is not limited thereto. The height IL1_H of the insulating layer IL1 may, for example, be between 15 μm and 200 μm (15 μm≤ IL1_H≤ 200 μm), and the via diameter IL1_D of the insulating layer IL1 may, for example, be less than 150 μm (IL1_D<150 μm), but the disclosure is not limited thereto.

Please continue to refer to FIG. 1, the electrical connection layer EL is formed in the via IL1_V of the insulating layer IL1.

In this embodiment, the following steps may be included to form the electrical connection layer EL in the via IL1_V of the insulating layer IL1, but the disclosure is not limited thereto.

(1) First, a conductive ball CB is formed in the via IL1_V of the insulating layer IL1. The conductive ball CB may be implanted in the via IL1_V of the insulating layer IL1 through, for example, using a conventional ball mount machine, and the disclosure is not limited thereto. In some embodiments, the number of the conductive ball CB may be one or multiple depending on requirements. In this embodiment, the conductive ball CB is shown as a single conductive ball, but the disclosure is not limited thereto. In some embodiments, the material of the conductive ball CB may include metal. For example, the material of the conductive ball CB may include tin, a tin alloy, or other suitable metals/alloys, but the disclosure is not limited thereto.

(2) Next, a reflow process is performed on the conductive ball CB to form the electrical connection layer EL. In this embodiment, the temperature, the time, or other process conditions of performing the reflow process on the conductive ball CB may be set depending on the included material of the conductive ball CB, and the disclosure is not limited thereto.

In this embodiment, the electrical connection layer EL is formed through performing the reflow process on the conductive ball CB, so that the electrical connection layer EL may be formed in the via IL1_V of the insulating layer IL1 having a relatively large aspect ratio, wherein the electrical connection layer EL may be electrically connected to the first conductive layer M1 and the second conductive layer M2 to reduce the possibility that the first conductive layer M1 and the second conductive layer M2 are not electrically connected, so as to improve the yield of the electronic device 10a.

In addition, in this embodiment, a distance EL_D between the electrical connection layer EL and the substrate SB is less than a distance IL2_D between the insulating layer IL2 and the substrate SB. The distance EL_D may, for example, be the distance measured between a part of the electrical connection layer EL farthest from the substrate SB in a normal direction n of the substrate SB and the substrate SB, and the distance IL2_D may, for example, be the distance measured between a part of the insulating layer IL2 farthest from the substrate SB in the normal direction n of the substrate SB and the substrate SB. Since the distance EL_D between the electrical connection layer EL and the substrate SB of this embodiment is less than the distance IL2_D between the insulating layer IL2 and the substrate SB, the horizontal height of the electrical connection layer EL may be less than the horizontal height of the insulating layer IL2 to reduce the possibility of unnecessary electrical connection generated between a subsequently formed film layer and the electrical connection layer EL. However, in other embodiments, the distance EL_D between the electrical connection layer EL and the substrate SB may be greater than the distance IL2_D between the insulating layer IL2 and the substrate SB.

So far, the manufacturing of the electronic device 10a of this embodiment is completed, but the disclosure is not limited thereto.

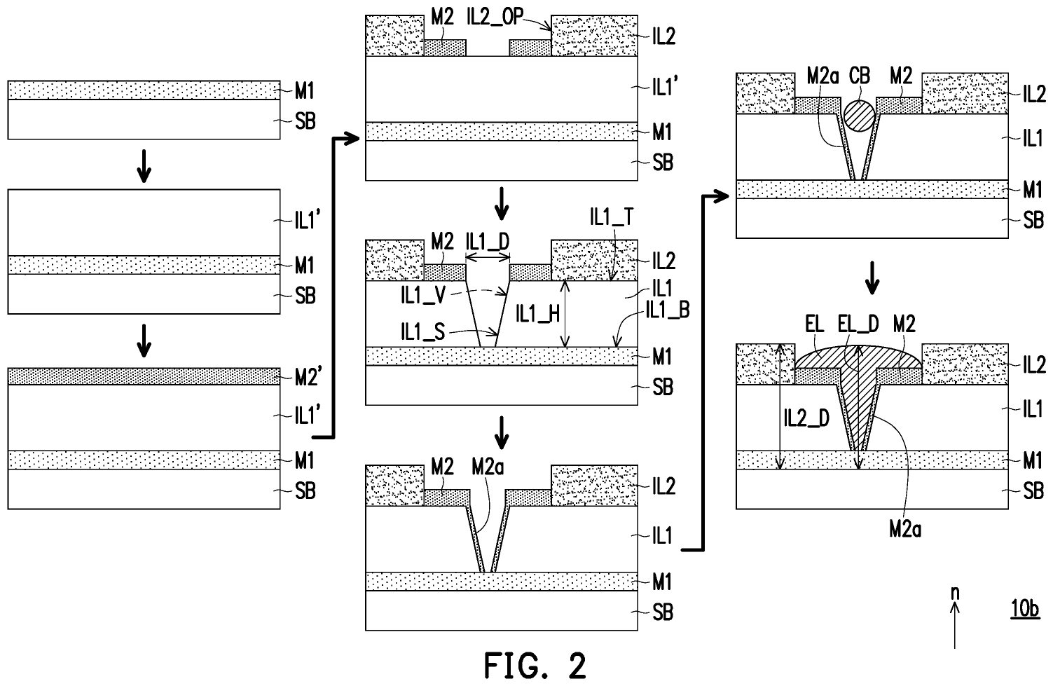

FIG. 2 is a schematic cross-sectional flowchart of a manufacturing method of an electronic device according to a second embodiment of the disclosure. It should be noted that the embodiment of FIG. 2 may continue to use the reference numerals and some content of the embodiment of FIG. 1, wherein the same or similar reference numerals are adopted to indicate the same or similar elements, and the description of the same technical content is omitted.

Please refer to FIG. 2. The main difference between a manufacturing method of an electronic device 10b of FIG. 2 and the manufacturing method of the electronic device 10a is that the former further includes forming a second conductive layer M2a on the sidewall IL1_S of the insulating layer IL1.

Specifically, in this embodiment, after forming the insulating layer IL1 having the via IL1_V and before forming the electrical connection layer EL in the via IL1_V of the insulating layer IL1, the second conductive layer M2a may be further formed on the sidewall IL1_S of the insulating layer IL1. In some embodiments, at least part of the sidewall IL1_S of the first insulating layer IL1 is covered by the second conductive layer M2a.

The second conductive layer M2a may be formed on the sidewall IL1_S of the insulating layer IL1 through, for example, performing a sputtering process, an electroless plating process, or other suitable processes, but the disclosure is not limited thereto. In some embodiments, the material of the second conductive layer M2a may include metal. For example, the material of the second conductive layer M2a may include copper, aluminum, or other suitable metals, but the disclosure is not limited thereto.

In this embodiment, the second conductive layer M2a is in the form of a continuous film layer and may be electrically connected to the first conductive layer M1 and/or the second conductive layer M2, but the disclosure is not limited thereto. In addition, the material of the second conductive layer M2a and the material of the first conductive layer M1 and/or the second conductive layer M2 may, for example, be the same as or different from each other, and the disclosure is not limited thereto.

In this embodiment, the electrical connection layer EL may cover the second conductive layer M2a on the sidewall IL1_S of the first insulating layer IL1, but the disclosure is not limited thereto.

In this embodiment, through forming the second conductive layer M2a on the sidewall IL1_S of the insulating layer IL1, the wetting ability between the sidewall IL1_S of the insulating layer IL1 and the conductive ball CB after the reflow process can be increased, so that the formed electrical connection layer EL may be almost completely filled in the via IL1_V of the insulating layer IL1 to further reduce the possibility that the first conductive layer M1 and the second conductive layer M2 are not electrically connected due to defects in the electrical connection layer EL, so as to improve the yield of the electronic device 10b.

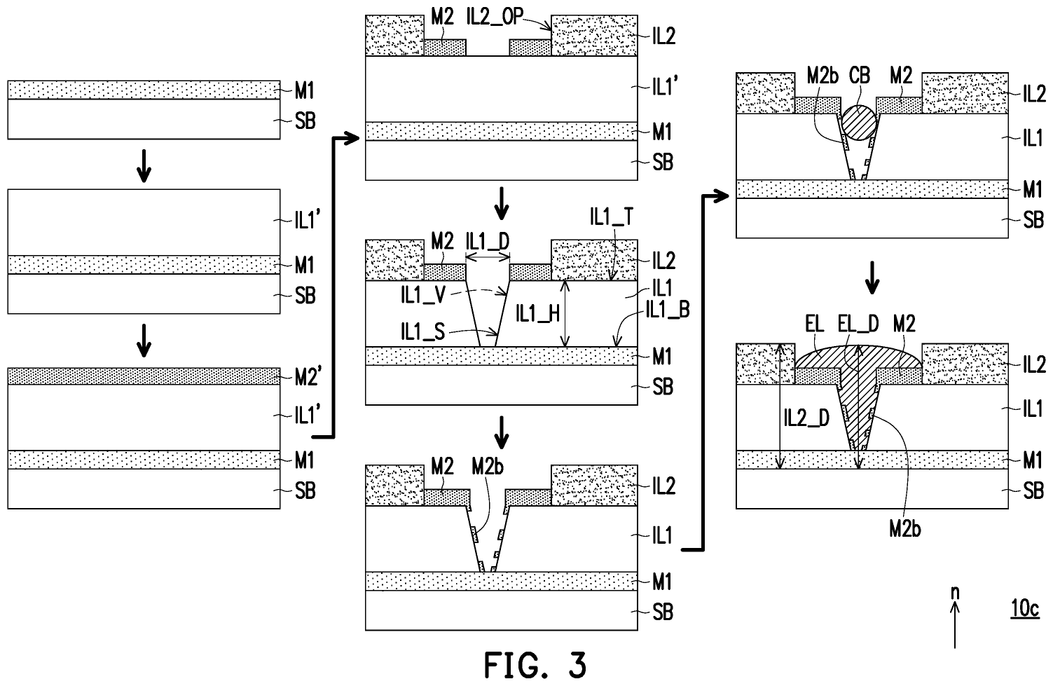

FIG. 3 is a schematic cross-sectional flowchart of a manufacturing method of an electronic device according to a third embodiment of the disclosure. It should be noted that the embodiment of FIG. 3 may continue to use the reference numerals and some content of the embodiment of FIG. 1, wherein the same or similar reference numerals are adopted to indicate the same or similar elements, and the description of the same technical content is omitted.

Please refer to FIG. 3. The main difference between a manufacturing method of an electronic device 10c of FIG. 3 and the manufacturing method of the electronic device 10a is that the former further includes forming a second conductive layer M2b on the sidewall IL1_S of the insulating layer IL1.

In detail, in this embodiment, after forming the insulating layer IL1 having the via IL1_V and before forming the electrical connection layer EL in the via IL1_V of the insulating layer IL1, the second conductive layer M2b may be formed on the sidewall IL1_S of the insulating layer IL1. In some embodiments, at least part of the sidewall IL1_S of the first insulating layer IL1 is covered by the second conductive layer M2b. In some embodiments, the second conductive layer M2b covers a part of the sidewall IL1_S adjacent to the second conductive layer M2, but does not cover a part of the sidewall IL1_S adjacent to the first conductive layer M1, but not limited thereto.

The second conductive layer M2b may be formed on the sidewall IL1_S of the insulating layer IL1 through, for example, performing a sputtering process, an electroless plating process, or other suitable processes, but the disclosure is not limited thereto. In some embodiments, the material of the second conductive layer M2b may include metal. For example, the material of the second conductive layer M2b may include copper, aluminum, or other suitable metals, but the disclosure is not limited thereto.

In this embodiment, the second conductive layer M2b is in the form of a discontinuous film layer. For example, the second conductive layer M2b may include multiple conductive patterns separated from each other. In some embodiments, most or all of the conductive patterns are not electrically connected to the first conductive layer M1 and the second conductive layer M2, but not limited thereto. In some embodiments, the conductive patterns may be electrically connected to the second conductive layer M2, but not electrically connected to the first conductive layer M1.

In this embodiment, the electrical connection layer EL may cover the second conductive layer M2b on the sidewall IL1_S of the first insulating layer IL1, but the disclosure is not limited thereto.

In this embodiment, through forming the second conductive layer M2b on the sidewall IL1_S of the insulating layer IL1, the wetting ability between the sidewall IL1_S of the insulating layer IL1 and the conductive ball CB after the reflow process can be increased, so that the formed electrical connection layer EL may be almost completely filled in the via IL1_V of the insulating layer IL1 to further reduce the possibility that the first conductive layer M1 and the second conductive layer M2 are not electrically connected due to defects in the electrical connection layer EL, so as to improve the yield of the electronic device 10c.

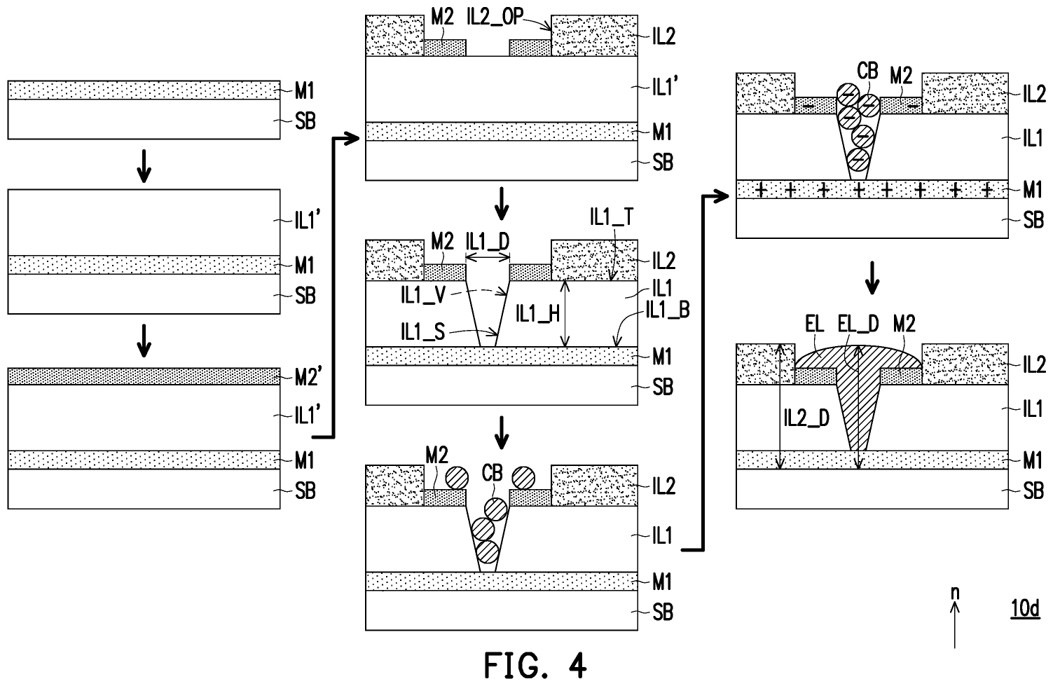

FIG. 4 is a schematic cross-sectional flowchart of a manufacturing method of an electronic device according to a fourth embodiment of the disclosure. It should be noted that the embodiment of FIG. 4 may continue to use the reference numerals and some content of the embodiment of FIG. 1, wherein the same or similar numbers are adopted to indicate the same or similar elements, and the description of the same technical content is omitted.

Please refer to FIG. 4. The main difference between a manufacturing method of an electronic device 10d of FIG. 4 and the manufacturing method of the electronic device 10a is that in the step of forming the electrical connection layer EL in the via IL1_V of the insulating layer IL1, the first metal layer M1 and the conductive ball CB have opposite charges.

In detail, in this embodiment, the following steps may be included to form the electrical connection layer EL in the via IL1_V of the insulating layer IL1, but the disclosure is not limited thereto.

(1) First, the conductive ball CB is formed in the via IL1_V of the insulating layer IL1. The conductive ball CB may be implanted in the via IL1_V of the insulating layer IL1 through, for example, using a conventional ball mount machine, and the disclosure is not limited thereto.

In this embodiment, the conductive ball CB is shown as multiple conductive balls, but the disclosure is not limited thereto. In addition, reference may be made to the foregoing embodiment for the material of the conductive ball CB, which will not be repeated here.

(2) Next, the first metal layer M1 carries a first charge, and the conductive ball CB carries a second charge. The method of enabling the first metal layer M1 to carry the first charge and the conductive ball CB to carry the second charge may be, for example, through applying an electric field, a magnetic field, or other suitable methods, but the disclosure is not limited thereto. In this embodiment, the first charge and the second charge have opposite charges. For example, the first charge may be a positive charge and the second charge may be a negative charge; or the first charge may be a negative charge and the second charge may be a positive charge. It should be noted that in some embodiments, the second metal layer M2 may also carry the second charge.

(3) Next, the reflow process is performed on the conductive ball CB to form the electrical connection layer EL. In this embodiment, the temperature, the time, or other process conditions of performing the reflow process on the conductive ball CB may be set depending on the included material of the conductive ball CB, and the disclosure is not limited thereto.

In this embodiment, through enabling the first metal layer M1 and the conductive ball CB to have opposite charges, the conductive ball CB may be attracted by the first conductive layer M1 through the via IL1_V of the insulating layer IL1, so that the formed electrical connection layer EL may be almost completely filled in the via IL1_V of the insulating layer IL1 to reduce the possibility that the first conductive layer M1 and the second conductive layer M2 are not electrically connected due to defects in the electrical connection layer EL, so as to improve the yield of the electronic device 10d.

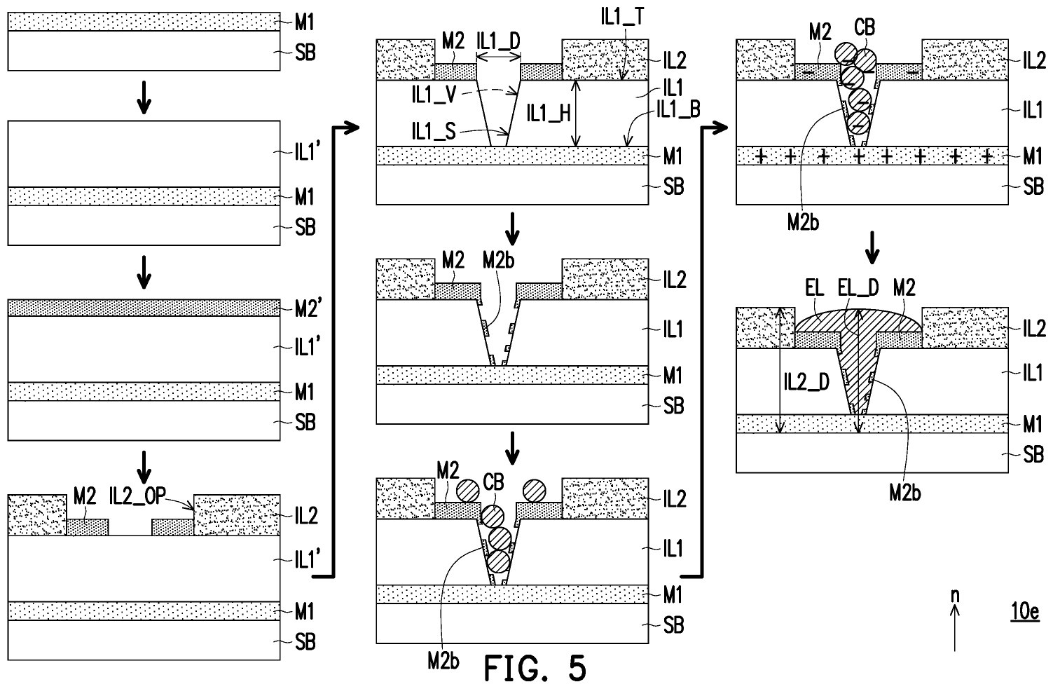

FIG. 5 is a schematic cross-sectional flowchart of a manufacturing method of an electronic device according to a fifth embodiment of the disclosure. It should be noted that the embodiment of FIG. 5 may continue to use the reference numerals and some content of the embodiments of FIG. 3 and FIG. 4, wherein the same or similar reference numerals are adopted to indicate the same or similar elements, and the description of the same technical content is omitted.

Please refer to FIG. 5. A manufacturing method of an electronic device 10e of FIG. 5 combines a part of the manufacturing method of the electronic device 10c and a part of the manufacturing method of the electronic device 10d.

In detail, in this embodiment, after forming the insulating layer IL1 having the via IL1_V, the second conductive layer M2b is formed on the sidewall IL1_S of the insulating layer IL1. Next, after forming the second conductive layer M2b on the sidewall IL1_S of the insulating layer IL1, the electrical connection layer EL is formed in the via IL1_V of the insulating layer IL1.

Based on this, in this embodiment, through forming the second conductive layer M2b on the sidewall IL1_S of the insulating layer IL1, the wetting ability between the sidewall IL1_S of the insulating layer IL1 and the conductive ball CB after the reflow process can be increased, so that the formed electrical connection layer EL may be almost completely filled in the via IL1_V of the insulating layer IL1 to reduce the possibility that the first conductive layer M1 and the second conductive layer M2 are not electrically connected due to defects in the electrical connection layer EL, so as to improve the yield of the electronic device 10e.

In addition, in this embodiment, through enabling the first metal layer M1 and the conductive ball CB to have opposite charges, the conductive ball CB may be attracted by the first conductive layer M1 through the via IL1_V of the insulating layer IL1, so that the formed electrical connection layer EL may be almost completely filled in the via IL1_V of the insulating layer IL1 to reduce the possibility that the first conductive layer M1 and the second conductive layer M2 are not electrically connected due to defects in the electrical connection layer EL, so as to improve the yield of the electronic device 10e.

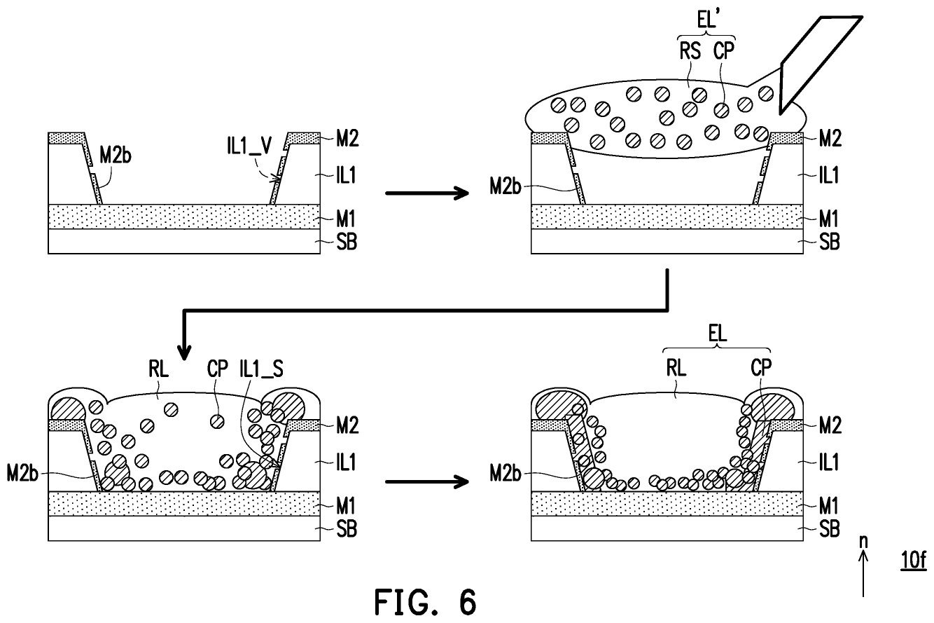

FIG. 6 is a schematic cross-sectional flowchart of a manufacturing method of an electronic device according to a sixth embodiment of the disclosure. It should be noted that the embodiment of FIG. 6 may continue to use the reference numerals and some content of the embodiment of FIG. 3, wherein the same or similar numbers are adopted to indicate the same or similar elements, and the description of the same technical content is omitted.

Please refer to FIG. 6. The main difference between a manufacturing method of an electronic device 10f of FIG. 6 and the manufacturing method of the electronic device 10c is that after forming the second conductive layer M2b on the sidewall IL1_S of the insulating layer IL1, the electrical connection layer EL including multiple conductive particles CP and a resin layer RL is formed in the via IL1_V of the insulating layer IL1.

In this embodiment, forming the electrical connection layer EL including the conductive particles CP and the resin layer RL may include performing the following steps, but the disclosure is not limited thereto.

(1) First, an electrical connection material layer EL′ is formed on the insulating layer IL1, wherein the electrical connection material layer EL′ overlaps with the via IL1_V of the insulating layer IL1 in the normal direction n of the substrate SB. The electrical connection material layer EL′ may be formed on the insulating layer IL1 through, for example, performing a coating process or other suitable processes, but the disclosure is not limited thereto. In this embodiment, the material of the electrical connection material layer EL′ includes the conductive particles CP and a resin RS, wherein the conductive particles CP are dispersed in the resin RS. The characteristics of the material of the conductive particles CP may be the same as or similar to the materials of the first conductive layer M1, the second conductive layer M2, and/or the second conductive layer M2b, so that the conductive particles CP tend to be close to the first conductive layer M1, the second conductive layer M2, and/or the second conductive layer M2b to be connected thereto during a subsequent heating process. In some embodiments, the material of the conductive particles CP may include copper, aluminum, or other suitable metals, and the resin RS may include epoxy, acrylic, or other suitable resins, but the disclosure is not limited thereto.

(2) Next, a heating process is performed on the electrical connection material layer EL′ to form the electrical connection layer EL. In this embodiment, the temperature, the time, or other process conditions of performing the heating process on the electrical connection material layer EL′ may be set depending on the included material of the electrical connection material layer EL′, and the disclosure is not limited thereto.

In this embodiment, through performing the heating process on the electrical connection material layer EL′, the conductive particles CP therein may move toward the first conductive layer M1, the second conductive layer M2, and/or the second conductive layer M2b, and may, for example, gather on the sidewall IL1_S of the insulating layer IL1 to be connected to the second conductive layer M2b, so that the first conductive layer M1 and the second conductive layer M2 may be electrically connected to each other through the conductive particles CP and the second conductive layer M2b to reduce the possibility that the first conductive layer M1 and the second conductive layer M2 are not electrically connected due to defects in the electrical connection layer EL, so as to improve the yield of the electronic device 10f.

In addition, in this embodiment, the resin RS forms the resin layer RL due to the heating process, wherein the resin layer RL may fill the via IL1_V of the insulating layer IL1, but the disclosure is not limited thereto.

In this embodiment, the distance between adjacent conductive patterns included in the second conductive layer M2b may be less than 20 μm, so that when the conductive particles CP gather on the sidewall IL1_S of the insulating layer IL1, the adjacent conductive patterns included in the second conductive layer M2b are electrically connected to each other, but the disclosure is not limited thereto. It is worth noting that in this embodiment, the second conductive layer M2a in the form of a continuous film layer may also be formed on the sidewall IL1_S of the insulating layer IL1, and the disclosure is not limited thereto.

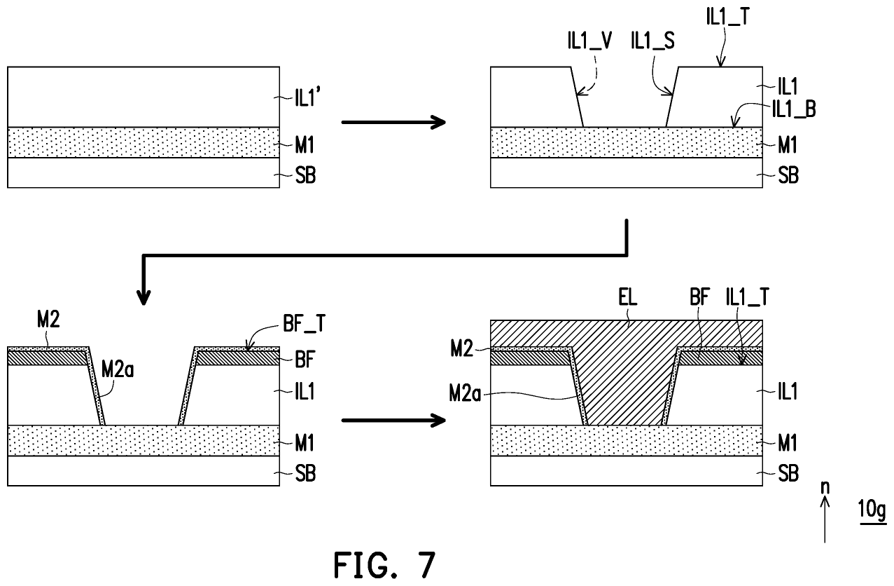

FIG. 7 is a schematic cross-sectional flowchart of a manufacturing method of an electronic device according to a seventh embodiment of the disclosure. It should be noted that the embodiment of FIG. 7 may continue to use the reference numerals and some content of the embodiment of FIG. 1, wherein the same or similar reference numerals are adopted to indicate the same or similar elements, and the description of the same technical content is omitted.

Please refer to FIG. 7. The main difference between a manufacturing method of an electronic device 10g of FIG. 7 and the manufacturing method of the electronic device 10a is that the former further includes forming a buffer layer BF between the insulating layer IL1 and the second conductive layer M2.

In detail, after forming the insulating layer IL1 and/or before forming the second conductive layer M2, the buffer layer BF may be formed on the top surface IL1_T of the insulating layer IL1. The forming method of the buffer layer BF may be through, for example, performing a sputtering process, an electroless plating process, or other suitable processes, but the disclosure is not limited thereto. In some embodiments, the material of the buffer layer BF may include a conductive material. For example, the material of the buffer layer BF may include silver, aluminum, gold, tungsten, copper, other metals, or other suitable materials, but the disclosure is not limited thereto. In some embodiments, the thickness of the buffer layer BF is less than or equal to 1 μm, which can reduce the possibility of warping of the electronic device 10g in subsequent processes.

After forming the buffer layer BF, a roughening process may be optionally performed to roughen the sidewall IL1_S of the insulating layer IL1. After performing the roughening process, the sidewall IL1_S of the insulating layer IL1 may have a relatively rough surface compared to the surface of the buffer layer BF due to the different included materials of the insulating layer IL1 and the buffer layer BF. In some embodiments, the roughening process may include a mechanical roughening process or a chemical roughening process, but the disclosure is not limited thereto. In addition, in this embodiment, the top surface IL1_T of the insulating layer IL1 is covered by the buffer layer BF without being affected by the roughening process. Therefore, the roughening process may enable the top surface IL1_T of the insulating layer IL1 to have a roughness less than the roughness of the sidewall IL1_S of the insulating layer IL1, but the disclosure is not limited thereto.

In addition, in this embodiment, the second conductive layer M2 may be formed through performing a sputtering process or an electroless plating process, and the second conductive layer M2a may be further disposed on the sidewall IL1_S of the insulating layer IL1. In some embodiments, the sidewall IL1_S of the insulating layer IL1 has a relatively large roughness due to the roughening process to improve the adhesion between the subsequently formed film layer and the sidewall IL1_S of the insulating layer IL1. Therefore, the second conductive layer M2a disposed on the sidewall IL1_S of the insulating layer IL1 may be in the form of a continuous film layer, but the disclosure is not limited thereto.

In addition, in this embodiment, the electrical connection layer EL may be formed on the second conductive layer M2 through performing an electroplating process or other suitable processes, but the disclosure is not limited thereto. In some embodiments, the material of the electrical connection layer EL may include metal. For example, the material of the electrical connection layer EL may include copper, aluminum, or other suitable metals, but the disclosure is not limited thereto. In other embodiments, the electronic device 10g may further include an electroless nickel immersion gold (ENIG) layer (not shown) formed on the electrical connection layer EL, which can facilitate the electrical connection between the electronic device 10g and electronic elements, but the disclosure is not limited thereto.

Based on this, in this embodiment, a top surface BF_T of the buffer layer BF and the sidewall IL1_S of the insulating layer IL1 may have relatively rough surfaces through performing the roughening process, so as to facilitate the attachment of the subsequently formed second conductive layer M2 to the top surface BF_T of the buffer layer BF and the sidewall IL1_S of the insulating layer IL1 to reduce the possibility of the second conductive layer M2 peeling off in subsequent processes, so as to improve the yield of the electronic device 10g. Moreover, through the arrangement of the buffer layer BF, the top surface IL1_T of the insulating layer IL1 is still relatively flat during the roughening process, which can improve the quality of signals transmitted by the electronic device 10g.

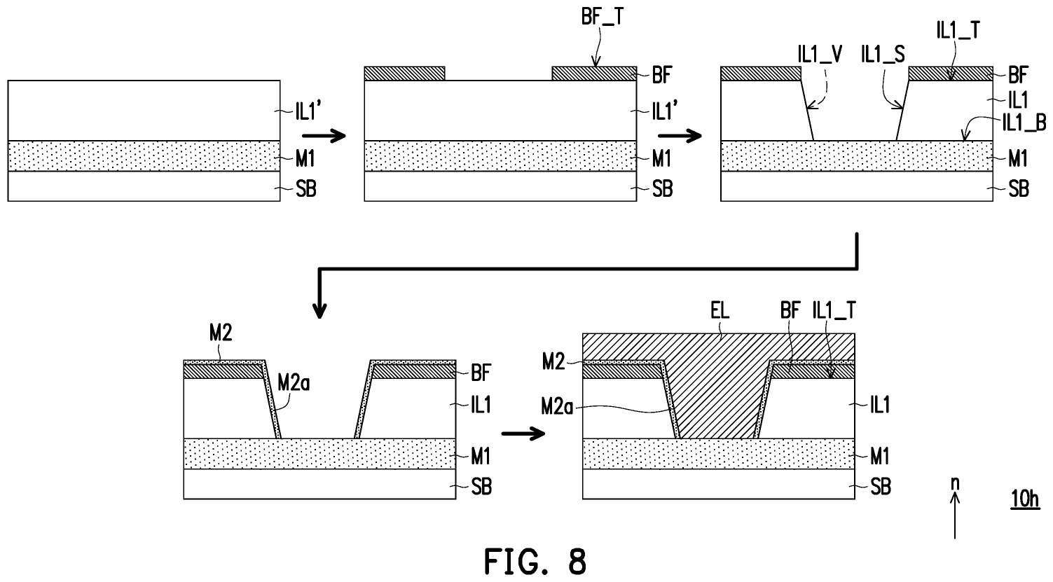

FIG. 8 is a schematic cross-sectional flowchart of a manufacturing method of an electronic device according to an eighth embodiment of the disclosure. It should be noted that the embodiment of FIG. 8 may continue to use the reference numerals and some content of the embodiment of FIG. 7, wherein the same or similar reference numerals are adopted to indicate the same or similar elements, and the description of the same technical content is omitted.

Please refer to FIG. 8. The main difference between a manufacturing method of an electronic device 10h of FIG. 8 and the manufacturing method of the electronic device 10g is that the via IL1_V of the insulating layer IL1 is formed by using the buffer layer BF as a mask.

In detail, after forming the insulating material layer IL1′, the buffer layer BF is formed on the insulating material layer IL1′, wherein the buffer layer BF exposes a part of the insulating material layer IL1′. That is, in this embodiment, the buffer layer BF is formed before forming the insulating layer IL1.

Afterwards, using the buffer layer BF as the mask, a laser drilling process is performed on the insulating material layer IL1′ to form the via IL1_V of the insulating layer IL1. In this embodiment, the buffer layer BF may have the characteristics of (1) high reflectivity (for example, greater than 90%) to laser and/or (2) low absorbance (A) (for example, less than 0.05) for laser to reduce the possibility that laser passes through the buffer layer BF and/or reduce the possibility that the buffer layer BF absorbs too much laser and generates defects, so as to improve the process stability of forming the via IL1_V of the insulating layer IL1, wherein the absorbance (A) conforms to the following relational expression:

A=log₁₀(I₀/I₁)

where I₀ is the intensity of laser incident on the buffer layer BF, and I₁ is the intensity of laser transmitted through the buffer layer BF.

Based on this, in this embodiment, through the arrangement of the buffer layer BF, the buffer layer BF may be used as the mask for performing the laser drilling process on the insulating material layer IL1′ and may adjust an included angle between the sidewall IL1_S of the formed insulating layer IL1 and the top surface IL1_T and/or the bottom surface IL1_B of the insulating layer IL1, so that the included angle between the sidewall IL1_S of the insulating layer IL1 and the top surface IL1_T and/or the bottom surface IL1_B of the insulating layer IL1 may tend to 90 degrees. In some embodiments, the included angle between the sidewall IL1_S of the insulating layer IL1 and the top surface IL1_T and/or the bottom surface IL1_B of the insulating layer IL1 may be greater than or equal to 80 degrees and less than or equal to 100 degrees.

Table 1 below shows the relationship between the wavelength of laser used in the laser drilling process and the included material of the buffer layer BF in this embodiment, but the disclosure is not limited thereto.

TABLE 1

| Laser used in the laser drilling process | | | Included material of buffer layer BF | |
|---|---|---|---|---|
| Laser source | Wavelength of laser | | Material with >90% | Material with absorbance < |
| | | | reflectivity to laser | 0.05 for laser |
| Carbon dioxide | 10640 | nm | Aluminum, copper, gold, | Molybdenum, aluminum, |
| laser | | | silver | copper, gold, silver |
| Fiber laser | 1070-1080 | nm | Aluminum, copper, gold, | Aluminum, copper, gold, |
| | | | silver | silver |
| Green laser | 532 | nm | Silver | Silver |

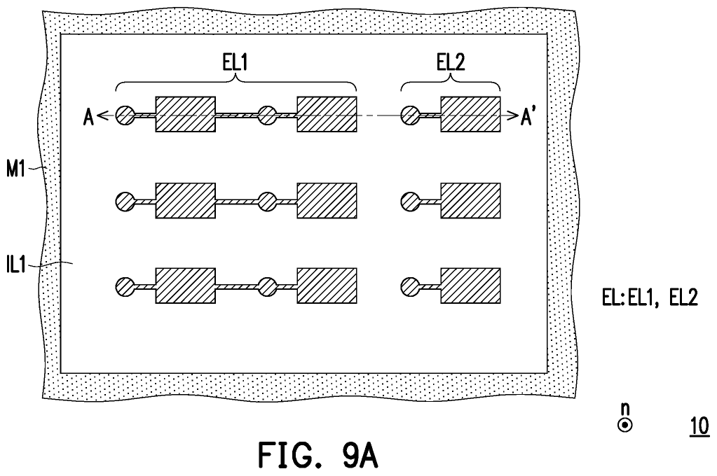

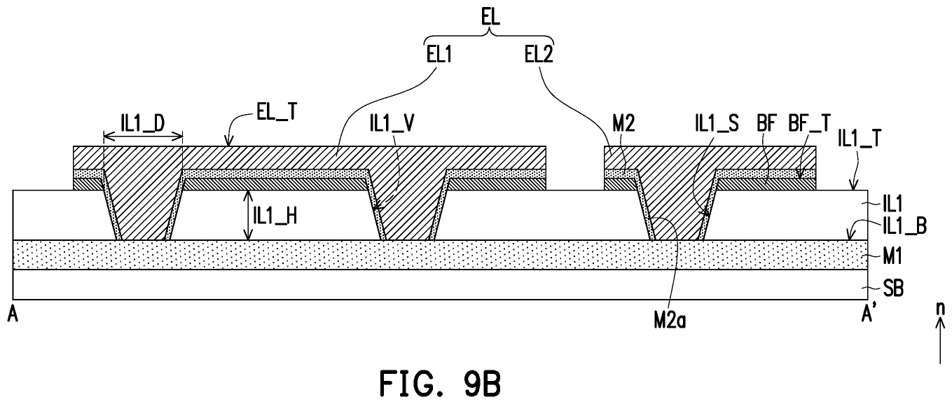

FIG. 9A is a schematic top view of an electronic device according to an embodiment of the disclosure, and FIG. 9B is a schematic cross-sectional view of an embodiment according to a section line A-A′ of FIG. 9A. It should be noted that an electronic device 10 shown in FIG. 9A and FIG. 9B may be any one of the electronic devices 10a to 10h, and the disclosure is not limited thereto. The following will briefly introduce the structure of the electronic device 10 of this embodiment with reference to FIG. 9A and FIG. 9B, wherein the same or similar reference numerals are used to denote the same or similar elements, and the description of the same technical content is omitted.

In this embodiment, the electronic device 10 is an antenna device and may receive high-frequency signals (for example, electromagnetic waves) from the outside or transmit high-frequency signals to the outside, but the disclosure is not limited thereto.

Please refer to FIG. 9A and FIG. 9B. The electronic device 10 of this embodiment may include the substrate SB, the first conductive layer M1, the insulating layer IL1, the second conductive layer M2, and the electrical connection layer EL. In this embodiment, the electrical connection layer EL may include multiple patterned structures. For example, the electrical connection layer EL includes a patterned electrical connection layer EL1 and a patterned electrical connection layer EL2, wherein a part of the top surface IL1_T of the insulating layer IL1 may be exposed between the adjacent patterned electrical connection layer EL1 and patterned electrical connection layer EL2, but the disclosure is not limited thereto. In some embodiments, a patterned structure included in the electrical connection layer EL may be filled in one or more vias IL1_V of the insulating layer IL1 to be electrically connected to the first conductive layer M1. For example, the patterned electrical connection layer EL1 is filled in two vias IL1_V of the insulating layer IL1, and the patterned electrical connection layer EL2 is filled in one via IL1_V of the insulating layer IL1, but the disclosure is not limited thereto.

The first conductive layer M1 is, for example, disposed on the substrate SB, wherein reference may be made to the foregoing embodiment for the included materials of the substrate SB and the first conductive layer M1, which will not be repeated here.

The insulating layer IL1 is, for example, disposed on the first conductive layer M1, wherein the insulating layer IL1 has the via IL1_V exposing a part of the first conductive layer M1. In this embodiment, the via IL1_V of the insulating layer IL1 has an aspect ratio greater than 1. In some embodiments, the roughness of the top surface IL1_T of the insulating layer IL1 may be less than the roughness of the sidewall IL1_S of the insulating layer IL1. Reference may be made to the foregoing embodiment for the included material of the insulating layer IL1, which will not be repeated here.

The second conductive layer M2 is, for example, disposed on the insulating layer IL1, wherein at least part of the sidewall IL1_S of the first insulating layer IL1 may be covered by the second conductive layer M2. Reference may be made to the foregoing embodiment for the included material of the second conductive layer M2, which will not be repeated here. The second conductive layer M2 may be electrically connected to the first conductive layer M1 through the via IL1_V of the insulating layer IL1. In detail, the second conductive layer M2a is disposed in the via IL1_V of the insulating layer IL1 and is in the form of a continuous film layer, but the disclosure is not limited thereto. In other embodiments, although not shown in FIG. 9B, at least part of the sidewall IL1_S of the first insulating layer IL1 may be covered by the second conductive layer M2b, wherein the second conductive layer M2b disposed in the via IL1_V of the insulating layer IL1 is in the form of a discontinuous film layer. For example, the second conductive layer M2b disposed in the via IL1_V of the insulating layer IL1 may include multiple conductive patterns separated from each other.

The electrical connection layer EL is, for example, disposed in the via IL1_V of the insulating layer IL1, wherein the electrical connection layer EL is electrically connected to the first conductive layer M1 and the second conductive layer M2. In some embodiments, the roughness of the top surface EL_T of the electrical connection layer EL may be less than the roughness of the sidewall IL1_S of the insulating layer IL1. Reference may be made to the foregoing embodiment for the included material of the electrical connection layer EL, which will not be repeated here.

In some embodiments, the electronic device 10 of this embodiment may further include the buffer layer BF. The buffer layer BF is, for example, disposed between the insulating layer IL1 and the second conductive layer M2, and is, for example, located on the top surface IL1_T of the insulating layer IL1. In some embodiments, the top surface BF_T of the buffer layer BF may have a roughness less than the roughness of the sidewall IL1_S of the insulating layer IL1. Reference may be made to the foregoing embodiment for the included material of the buffer layer BF, which will not be repeated here.

In summary, in the electronic device provided by some embodiments of the disclosure, the electrical connection layer may be formed in the via of the insulating layer having a relatively large aspect ratio through the process of forming the electrical connection layer according to each embodiment of the disclosure, and the first conductive layer and the second conductive layer may be electrically connected to each other by using the electrical connection layer to reduce the possibility that the first conductive layer and the second conductive layer are not electrically connected, so as to improve the yield of the electronic device provided by some embodiments of the disclosure.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. A manufacturing method of an electronic device, comprising:
forming a first conductive layer on a substrate; and
forming a first insulating layer and a second conductive layer on the first conductive layer, wherein the first insulating layer is disposed between the second conductive layer and the first conductive layer, and the first insulating layer has a via exposing a part of the first conductive layer,
wherein an aspect ratio of the via of the first insulating layer is greater than 1,
wherein at least part of a sidewall of the first insulating layer is covered by the second conductive layer.

2. The manufacturing method of the electronic device according to claim 1, further comprising:
forming an electrical connection layer in the via of the first insulating layer, wherein the electrical connection layer covers the second conductive layer on the sidewall of the first insulating layer.

3. The manufacturing method of the electronic device according to claim 2, wherein the step of forming the electrical connection layer in the via of the first insulating layer comprises:
forming a conductive ball in the via of the insulating layer; and
performing a reflow process on the conductive ball.

4. The manufacturing method of the electronic device according to claim 3, wherein the step of forming the electrical connection layer in the via of the first insulating layer further comprises:
before performing the reflow process on the conductive ball, enabling the first metal layer to carry a first charge, and enabling the conductive ball to carry a second charge, wherein the first charge and the second charge have opposite charges.

5. The manufacturing method of the electronic device according to claim 2, wherein the step of forming the electrical connection layer in the via of the first insulating layer comprises:
forming an electrical connection material layer on the insulating layer, wherein the electrical connection material layer overlaps with the via of the insulating layer in a normal direction of the substrate, a material of the electrical connection material layer comprises a plurality of conductive particles and a resin, and the conductive particles are dispersed in the resin; and
performing a heating process on the electrical connection material layer, so that the conductive particles are disposed on the sidewall of the first insulating layer and are electrically connected to the first conductive layer and the second conductive layer.

6. The manufacturing method of the electronic device according to claim 1, wherein the step of forming the first insulating layer and the second conductive layer on the first conductive layer comprises:
forming a first insulating material layer on the first conductive layer;
forming a second insulating layer on the first insulating material layer, wherein the second insulating layer has an opening exposing a part of the first insulating material layer;
forming the second conductive layer on the first insulating material layer, wherein the second conductive layer exposes a part of the first insulating material layer; and
removing a part of the first insulating material layer to form the first insulating layer having the via.

7. The manufacturing method of the electronic device according to claim 1, wherein the step of forming the first insulating layer and the second conductive layer on the first conductive layer further comprises:
forming a buffer layer between the first insulating layer and the second conductive layer, wherein the buffer layer is disposed on a top surface of the first insulating layer; and
performing a roughening process to roughen the sidewall of the first insulating layer.

8. The manufacturing method of the electronic device according to claim 7, wherein the via of the first insulating layer is formed by using the buffer layer as a mask.

9. The manufacturing method of the electronic device according to claim 8, wherein a laser drilling process is performed to form the via of the first insulating layer.

10. The manufacturing method of the electronic device according to claim 9, wherein a reflectivity of the buffer layer to laser is greater than 90% and/or an absorbance for laser is less than 0.05.

11. An electronic device, comprising:
a substrate;
a first conductive layer, disposed on the substrate;
a first insulating layer, disposed on the first conductive layer, wherein the first insulating layer has a via exposing a part of the first conductive layer; and
a second conductive layer, disposed on the first insulating layer, wherein the second conductive layer is electrically connected to the first conductive layer through the via of the first insulating layer,
wherein an aspect ratio of the via of the first insulating layer is greater than 1,
wherein at least part of a sidewall of the first insulating layer is covered by the second conductive layer.

12. The electronic device according to claim 11, wherein the second conductive layer covering the at least part of the sidewall of the first insulating layer is a continuous film layer.

13. The electronic device according to claim 11, wherein the second conductive layer covering the at least part of the sidewall of the first insulating layer is a discontinuous film layer.

14. The electronic device according to claim 11, further comprising:
an electrical connection layer, disposed in the via of the first insulating layer, wherein the electrical connection layer is electrically connected to the first conductive layer and the second conductive layer, and the electrical connection layer covers the second conductive layer on the sidewall of the first insulating layer.

15. The electronic device according to claim 14, wherein the electrical connection layer comprises a conductive particle and a resin layer, wherein the conductive particle is electrically connected to the first conductive layer and the second conductive layer, and the resin layer is filled in the via of the first insulating layer.

16. The electronic device according to claim 11, further comprising a buffer layer disposed between the first insulating layer and the second conductive layer, and located on a top surface of the first insulating layer.

17. The electronic device according to claim 16, wherein a roughness of a top surface of the buffer layer is less than a roughness of the sidewall of the first insulating layer.

18. The electronic device according to claim 16, wherein a roughness of the top surface of the first insulating layer is less than a roughness of the sidewall of the first insulating layer.

19. The electronic device according to claim 14, wherein a roughness of a top surface of the electrical connection layer is less than a roughness of the sidewall of the first insulating layer.

20. The electronic device according to claim 11, wherein an included angle between the sidewall of the first insulating layer and a top surface and/or a bottom surface of the first insulating layer is greater than or equal to 80 degrees and less than or equal to 100 degrees.
